(19) United States
(12) Patent Application Publication
(10) Pub. No.: US 2019/0157425 A1
(43) Pub. Date: May 23, 2019

(54) SEMICONDUCTOR DEVICE AND FABRICATION METHOD THEREOF

(71) Applicants: Semiconductor Manufacturing International (Shanghai) Corporation, Shanghai (CN); SMIC New Technology Research and Development (Shanghai) Corporation, Shanghai (CN)

(72) Inventors: Yi Qun LIU, Shanghai (CN); Yong Gen HE, Shanghai (CN)

(21) Appl. No.: 16/188,917

(22) Filed: Nov. 13, 2018

(30) Foreign Application Priority Data
Nov. 22, 2017 (CN) 201711172879.8

(51) Int. Cl. H01L 29/66; H01L 21/324; H01L 21/02; H01L 29/78; H01L 29/16; H01L 29/161; H01L 29/08

(52) U.S. Cl. CPC H01L 29/66636; H01L 29/66795; H01L 21/3247; H01L 21/02645; H01L 21/02529; H01L 29/0847; H01L 29/7848; H01L 29/1608; H01L 29/161; H01L 29/7851; H01L 21/02532

(57) ABSTRACT

Semiconductor device and fabrication method are provided. The method includes: providing a base substrate having a gate structure formed thereon; forming initial trenches in the base substrate on sides of each gate structure; smoothing inner wall surfaces of the initial trenches to form trenches from the initial trenches, wherein a corner between a bottom surface and a sidewall of each trench is rounded; forming a seed layer on inner walls of each trench, wherein the seed layer covers all inner walls of each trench; and forming source/drain layers on surfaces of the seed layers in the trenches.

### CROSS-REFERENCES TO RELATED APPLICATION

This application claims the priority of Chinese Patent Application No. 201711172879.8, filed on Nov. 22, 2017, the content of which is incorporated herein by reference in its entirety.

### TECHNICAL FIELD

The present disclosure generally relates to the field of semiconductor technologies and more particularly, relates to a semiconductor device and its fabrication method.

### BACKGROUND

Metal-oxide-semiconductor (MOS) transistors are one of the most important components in modern integrated circuits. A basic structure of the MOS transistor includes a semiconductor substrate, a gate structure on a surface of the semiconductor substrate, and source and drain doped regions in the semiconductor substrate on both sides of the gate structure. In a MOS transistor, voltages are applied on the gate structures to control currents flowing through channels at bottom of the gate structures and to produce on/off signals.

With continuous development in semiconductor technologies, the control capability of the conventional planar MOS transistor over a channel current becomes weaker, which causes serious leakage current. A fin field effect transistor (FinFET) is an emerging multi-gate device. The FinFET generally includes one or more protruding fins on a surface of a semiconductor substrate, a gate structure across a length portion of the fin and covering a portion of each of top and sidewall surfaces of the fin, and source and drain doped regions in the fin on both sides of the gate structure.

However, there is still a need to improve performance of semiconductors devices formed by planar MOS transistors or FinFETs. The disclosed devices and methods are directed to at least partially alleviate one or more problems set forth above and to solve other problems in the art.

### SUMMARY

One aspect of the present disclosure includes a method for fabricating a semiconductor structure. The method includes: providing a base substrate having a gate structure formed thereon; forming initial trenches in the base substrate on sides of each gate structure; smoothing inner wall surfaces of the initial trenches to form trenches from the initial trenches, wherein a corner between a bottom surface and a sidewall of each trench is rounded; forming a seed layer on inner walls of each trench, wherein the seed layer covers all inner walls of each trench; and forming source/drain layers on surfaces of the seed layers in the trenches.

Another aspect of the present disclosure includes a semiconductor structure. The semiconductor structure includes: a base substrate; a gate structure on the base substrate; trenches in the base substrate on sides of the gate structure; seed layers on the inner walls of the trenches, where seed layers may cover the inner walls of the trenches; and source/drain layers on the seed layers in the trenches.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-3 illustrate semiconductor structures corresponding to certain stages for forming a semiconductor device;

FIGS. 4-8 illustrate semiconductor structures corresponding to certain stages for forming an exemplary semiconductor device according to various disclosed embodiments of the present disclosure; and

FIG. 9 illustrates an exemplary fabrication method for forming a semiconductor structure according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

Semiconductor device and fabrication method are provided. The method includes: providing a base substrate having gate structures formed thereon; forming initial trenches in the base substrate on sides of each gate structure; smoothing inner wall surfaces of the initial trenches to form trenches from the initial trenches, wherein a corner between a bottom surface and a sidewall of each trench is rounded; forming a seed layer on inner walls of each trench, wherein the seed layer covers all inner walls of each trench; and forming source/drain layers on surfaces of the seed layers in the trenches.

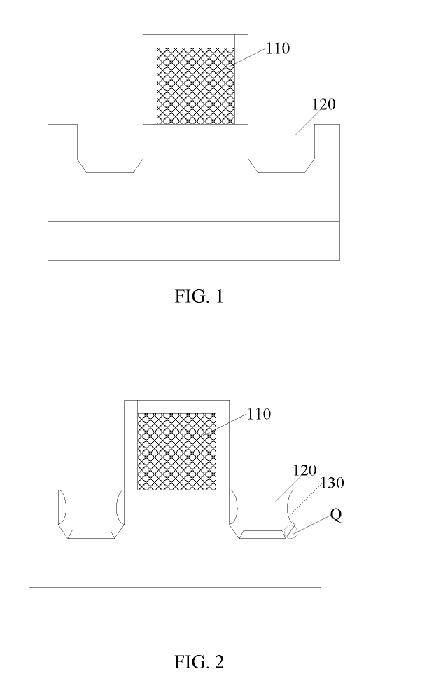

FIGS. 1-3 illustrate semiconductor structures corresponding to certain stages for forming a semiconductor device.

Referring to FIG. 1, a base substrate with a gate structure 110 on the base substrate may be provided. Trenches 120 may be formed in the base substrate on sides of the gate structure 110.

Referring to FIG. 2, seed layers 130 may be formed on inner sidewalls of the trenches 120.

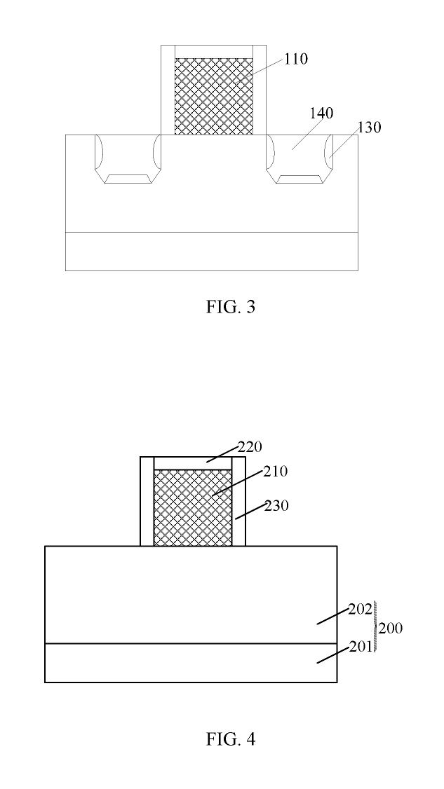

Referring to FIG. 3, source/drain layers 140 may be formed on surfaces of the seed layers 130 in the trenches 120 (referring to FIG. 2).

The trenches 120 may be formed using an anisotropic dry etching process, which may be directional in etching. After the formation of the trenches 120, the transition from a sidewall surface of the trench 120 to a bottom surface of the trench 120 may be acute and the lattice at a corner Q may be poor in integrity. The residual byproducts at the corner Q may be difficult to clean or remove. Correspondingly, the corner Q may have more defects, and the surface state at the corner Q between the bottom of the trench 120 and the sidewall of the trench 120 may be high, which may cause the seed layer 130 difficult to grow at the corner Q.

In order to provide the source/drain layers 140 with large growth space, the thickness of the seed layers 130 may not be too large. The seed layers 130 may cover a portion of the inner walls of the trenches 120 d may not be formed at the corners Q. Correspondingly, a partial portion of the source/drain layers 140 may directly grow at surfaces of the corners Q and the source/drain layers 140 may grow at the corners Q without the seed layers 130 as transition layers, which may result in more lattice defects in the source/drain layers 140 and lower quality of the source/drain layers 140, and the reduced performance of semiconductor devices.

The present disclosure provides a semiconductor device and its fabricating method. The method includes: forming initial trenches in the base substrate on sides of a gate structure; forming trenches from the initial trenches by smoothing inner walls of the initial trenches, where the corners between the bottom surface and the sidewall of the trench may be rounded; forming seed layers, which cover the inner walls of the trenches, at the inner walls of the trenches; and forming source/drain layers on the surfaces of the seed layers in the trenches. This method improves the performance of semiconductor devices.

FIGS. 4-8 illustrate semiconductor structures corresponding to certain stages for forming an exemplary semiconductor device according to various disclosed embodiments of the present disclosure.

Referring to FIG. 4, a base substrate 200 with a gate structure 210 on the base substrate 200 may be provided.

For illustration purposes, the present disclosure is described using FinFET as an example for the semiconductor device. Correspondingly, the base substrate 200 may include a semiconductor substrate 201 and fins 202 protruding from the semiconductor substrate 201.

The semiconductor substrate 201 may be made of semiconductor materials including single crystalline silicon, polycrystalline silicon and/or amorphous silicon. The semiconductor substrate 201 may further be made of semiconductor materials including germanium, silicon germanium, gallium arsenide and/or any other suitable semiconductor material(s). In one embodiment, the semiconductor substrate 201 may be made of single crystalline silicon.

In one embodiment, the fins 202 may be formed by patterning the semiconductor substrate 201. In other embodiments, the fins 202 may be formed by: after forming a fin material layer on the semiconductor substrate, patterning the fin material layer to form the fins.

In one embodiment, isolation structures may be further formed on the semiconductor substrate 201 to cover a portion of the sidewalls of the fins 202. The isolation structures have top surfaces lower than the top surfaces of the fins 202. The isolation structures may be made of silicon dioxide, for example.

In other embodiments, the semiconductor device may be a planar MOS transistor, and the base substrate may be a planar semiconductor substrate.

The gate structure 210 may include a gate dielectric layer on the base substrate and a gate layer on the gate dielectric layer. The gate dielectric layer may be made of silicon dioxide and the gate layer may be made of polycrystalline silicon. In one embodiment, the gate dielectric layer may cross the fins 202, and may cover a portion of the sidewalls and a portion of the top surfaces of the fins 202.

A top protection layer 220 may be formed on the top surface of the gate structure 210. The top protection layer 220 may be made of silicon nitride, for example.

In one embodiment, the method may further include: forming spacers 230 on the sidewalls of the gate structures 210. The gate spacers may be made of silicon nitride, for example.

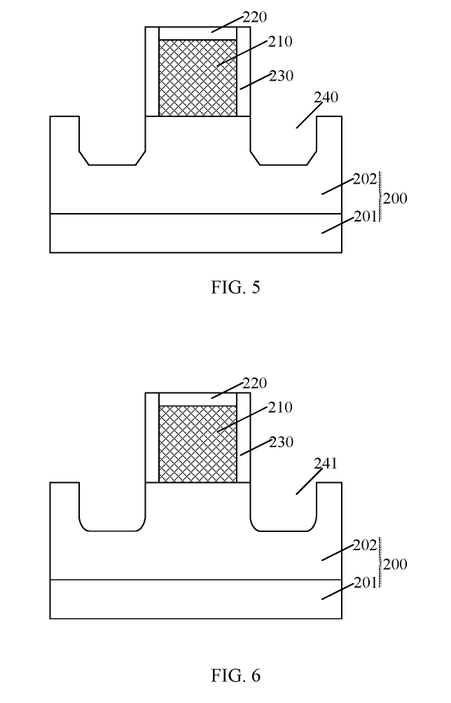

Referring to FIG. 5, initial trenches 240 may be formed in the base substrate 200 on sides of the gate structure 210.

In one embodiment, the initial trenches 240 may be formed in the fins 202 on sides of the gate structure 210 and spacers 230.

In some embodiments, the initial trenches 240 may be formed by an anisotropic dry etching process. The initial trenches 240 may be U shape. A size of the initial trench 240 along a direction in parallel with the channel may be approximately 50 nm to 60 nm. A depth of the initial trench 240 may be approximately 50 nm to 60 nm.

Referring to FIG. 6, the inner wall surfaces of the initial trenches 240 may be smoothed to form trenches 241 from the initial trenches 240, and the corners between the bottom surfaces and the sidewalls of the trenches 241 may be rounded.

In one embodiment, the surface smoothing process may include an annealing treatment. The inner walls of the initial trenches 240 may be treated by an annealing process. The surface smoothing process may provide smooth surfaces at the corners between the bottom and the sidewalls of the trenches 241, provide gradual transitions from the sidewall surfaces to the bottom surfaces of the trenches 241, and also provide less surface roughness at the corners between the bottom and the sidewalls of the trenches 241. The surface smoothing process may also repair the lattice damage at the corners between the bottom and the sidewalls of the initial trenches 240. Correspondingly, the surface smoothing process may reduce surface defects and lower the surface state density at the corners between the bottom and the sidewalls of the initial trenches 241.

The surface smoothing of the inner walls of the initial trenches 240 using the annealing process may include: cleaning and reconstruction the crystal lattices of the inner walls of the initial trenches 240 at a high temperature and low pressure, which may reduce lattice planes (111) with higher surface energy and make the inner walls of the trenches 241 smoother than the inner walls of the initial trenches 240.

The annealing treatment may be a spike annealing, which may be completed in a shorter period of time and have less high temperature effect on other structural components.

In the annealing treatment: gases may include N₂, H₂ or a combination thereof; an annealing temperature may be approximately 800 degrees Celsius to 1000 degrees Celsius; and an annealing pressure may be approximately 5 torr to 50 torr.

In the annealing treatment, the required pressure may decrease as the applied temperature decreases. The annealing temperature may be approximately 800 degrees Celsius to 1000 degrees Celsius. If the annealing temperature is less than 800 degrees Celsius, the cleaning and smoothing progress may not be completed. If the annealing temperature is greater than 1000 degrees Celsius, the pre-process ion implanting depth may be affected.

When forming the initial trenches 240, polymer byproducts may be produced. The polymer byproducts at the corners of the initial trenches 240 may be difficult to remove during the cleaning process. The polymer byproducts at the corners of the initial trenches 240 may be removed during the surface smoothing process.

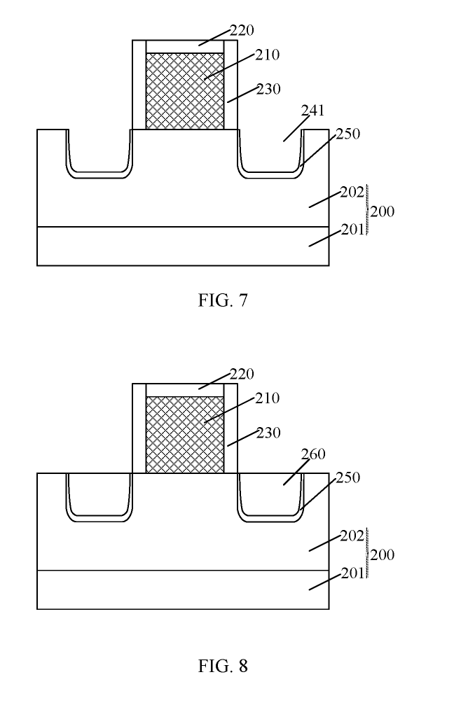

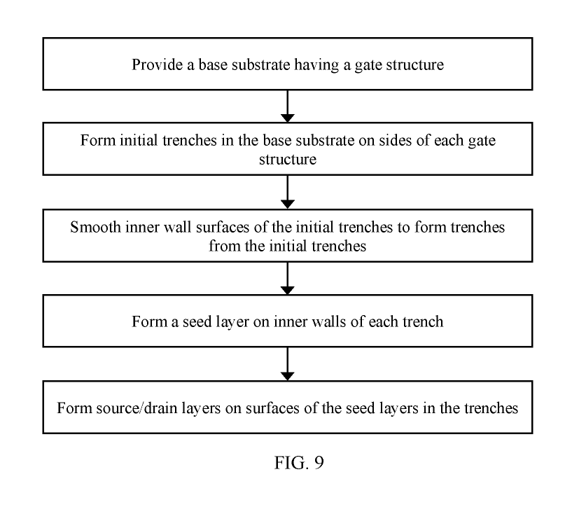

Referring to FIG. 7, seed layers 250 may be formed on inner walls of the trenches 241 and seed layers 250 may cover the inner walls of the trenches 241.

In one embodiment, when the semiconductor device is an N-type device, the seed layers 250 may be made of silicon or silicon carbide with conductive ions and the conductive ions may be N-type conductive ions such as phosphorus ions. When the semiconductor device is a P-type device, the seed layers 250 may be made of silicon germanium with conductive ions and the conductive ions may be P-type conductive ions such as boron ions.

In other embodiments, when the semiconductor device is an N-type device, the seed layers may be made of silicon.

The seed layers 250 may be doped with conductive ions and the concentration of the conductive ions in the seed layers 250 may be less than the concentration of the conductive ions in subsequent source/drain layers.

In one embodiment, the concentration of the conductive ions in the seed layers 250 may be approximately 1% to 5% of the concentration of conductive ions in subsequent source/drain layers.

The seed layers 250 may provide seeds for the growth of the subsequent source/drain layers. The seed layers 250 may have less lattice misalignment, which may allow less lattice misalignment of the subsequent source/drain layers on the seed layers 250.

The surfaces at the corners between the bottom and the sidewalls of the trenches 241 may have less defects and the seed layers 250 may be easily formed at the corners between the bottom and sidewalls of the trenches 241. With a constant thickness of the seed layer 250, the seed layer 250 may cover the inner walls of the trench 241.

In one embodiment, the seed layers 250 may be made of silicon germanium with conductive ions and the conductive ions may be boron ions. Correspondingly, the seed layers 250 may be formed by an epitaxial growth process: gases may include SiH₂Cl₂, GeH₄, B₂H₆ and HCl; a flow rate of SiH₂Cl₂ may be approximately 100 sccm to 200 sccm; a flow rate of GeH₄ may be approximately 8 sccm to 21 sccm; a flow rate of B₂H₆ may be approximately 15 sccm to 50 sccm; a flow rate of HCl may be approximately 50 sccm to 100 sccm; a temperature may be approximately 660 degrees Celsius to 680 degrees Celsius; and a chamber pressure may be approximately 100 torr to 200 torr.

In the epitaxial growth process for forming the seed layers 250, the flow rate of SiH₂Cl₂ and the flow rate of GeH₄ may be chosen to be greater than conventional flow rates. The reaction gases may be sufficient to first satisfy the (100) lattice planes and then the (110) lattice planes to grow the seed layers 250 and may further have sufficient amount to satisfy the (111) lattice planes to grow the seed layers 250, which may reduce the differences in growth rates of the seed layers 250 for different lattice planes and may further increase the probability of forming the seed layers 250 on the corner surfaces between the bottom and side walls of the trenches 241.

In one embodiment, the semiconductor device is an N-type device and the seed layers may be made of silicon. The seed layers may be formed by an epitaxial growth process: gases may include SiH₂Cl₂ and HCl; a flow rate of SiH₂Cl₂ may be approximately 100 sccm to 200 sccm; a flow rate of HCl may be approximately 50 sccm to 100 sccm; a temperature may be approximately 700 degrees Celsius to 750 degrees Celsius; a chamber pressure may be approximately 100 torr to 200 torr.

In the epitaxial growth process for forming the seed layers 250, the flow rate of SiH₂Cl₂ and the flow rate of GeH₄ may be chosen to be greater than conventional flow rates. The reaction gases may be sufficient to first satisfy the (100) lattice planes and then the (110) lattice planes to grow the seed layers 250 and may further have sufficient amount to satisfy the (111) lattice planes to grow the seed layers 250, which may reduce the differences in growth rates of the seed layers 250 for different lattice planes and may further increase the probability of forming the seed layers 250 on the corner surfaces between the bottom and side walls of the trenches 241.

In one embodiment, the average thickness of the seed layer 250 at the bottom of the trench 241 may be larger than the average thickness of the seed layer 250 at the sidewall of the trench 241 because the seed layers 250 may grow at the fastest rate along the normal to the (100) lattice plane of the seed layers 250.

The average thickness of the seed layer 250 at the bottom of the trench 241 may be larger than the average thickness of the seed layer 250 at the sidewall of the trench 241. Thinner thickness of the seed layer 250 at the sidewall of the trench 241 may provide advantages, for example, may reduce the distance between the subsequent source/drain layer and the channel, fully exert stress on the channel from the source/drain layer, improve the carrier mobility in the channel, and may improve the performance of semiconductor devices. Thicker thickness of the seed layer 250 at the bottom of the trench 241 may reduce the size of the subsequent source/drain layers in a direction perpendicular to a surface of the semiconductor substrate 201, and may have the advantage of maintaining the stress from the source/drain layers in the channel and may prevent the relaxation.

In one embodiment, the average thickness of the seed layer 250 at the bottom of the trench 241 may be approximately 10 nm to 16 nm, and the average thickness of the seed layer 250 at the sidewall of the trench 241 may be approximately 6 nm to 8 nm.

Referring to FIG. 8, source/drain layers 260 may be formed on the surfaces of the seed layers 250 in the trenches 241.

The source/drain layers 260 may be doped with conductive ions.

When the semiconductor device is an N-type device, the seed layers 260 may be made of silicon, silicon germanium or silicon carbide with conductive ions and the conductive ions may be N-type conductive ions, such as phosphorus ions. When the semiconductor device is a P-type device, the seed layers 260 may be made of silicon germanium with conductive ions and the conductive ions may be P-type conductive ions such as, boron ions.

When the seed layers 250 may be silicon germanium with conductive ions and the source/drain layers 260 may be silicon germanium with conductive ions, the concentration of germanium ions in the source/drain layers 260 may be greater than the concentration of germanium ions in the seed layers 250.

The source/drain layers 260 may be formed by an epitaxial growth process.

With a constant thickness of the seed layer 250, the seed layer 250 may cover the inner walls of the trench 241. The seed layer 250 may be served as a transition buffer layer for the growth of the source/drain layer 260, which may avoid the growth of the source/drain layer 260 on a portion of the inner wall surface of the trench 241 during the formation of the source/drain layer 260. The source/drain layer 260 may only grow on the surface of the seed layer 250, which may reduce the lattice defects of the source/drain layer 260 at the corner between the bottom and the side wall of the trench 241 and may improve the quality of the source/drain layer 260 and the performance of the semiconductor device.

The quality of the source/drain layers 260 may be improved, which may improve the stress of the source/drain layers 260 exerted on the channel, the carrier mobility in the channel, the driving current of the semiconductor device, and the qualified rate of the semiconductor devices.

In one embodiment, the concentration of the conductive ions in the seed layers 250 may be approximately 4E18 atoms/cm³-6E18 atoms/cm³, for example, approximately 5E18 atoms/cm³. The concentration of the conductive ions in the source/drain layers 260 may be approximately 2E20 atoms/cm³-3E20 atoms/cm³.

In the epitaxial growth process for forming the source/drain layers, the gases including HCl may be used for selective growth of the source/drain layers.

Conventionally, the seed layers may not grow at the corners. The source/drain layers may extend from the defects at the corners to top surfaces of the source/drain layers. The top of the source/drain layers, which may be etched by HCl during the formation of the source/drain layers, may have poor quality, and the top surface of the source/drain layers may form concave defects.

In one embodiment, the source/drain layers 260 may grow on the surfaces of the seed layers 250 and the source/drain layers 260 from the bottom to the top may have better quality. The top material of the source/drain layers 260 may not be etched by HCl during the formation of the source/drain layers 260, which may avoid concave defects at the top surfaces of the source/drain layers 260 and increase the stress of source/drain layers 260 exerted on the channel.

In one embodiment, the method may further include: after the formation of the source/drain layers 260, forming a bottom dielectric layer on the base substrate 200, the isolation structure, the seed layers 250 and the source/drain layers 260; covering the sidewalls of the gate structure 210 by the bottom dielectric layer; removing the top protection layer 220 to expose the top surface of the gate structure 210 during the formation of the bottom dielectric layer; after the formation of the bottom dielectric layer, removing the gate structure to form a gate opening in the bottom dielectric layer; and forming a metal gate structure in the gate opening.

Correspondingly, the disclosure embodiment also provides a semiconductor device, as illustrated in FIG.8, including: a base substrate 200; a gate structure on the base substrate 210; trenches 241 in the base substrate 200 on sides of the gate structure 210 (referring to FIG. 6), where corners from the bottom surfaces to the sidewalls of the trenches 241 may be rounded; seed layers 250 on the inner walls of the trenches 241, where seed layers 250 may cover the inner walls of the trenches 241; and source/drain layers 260 on the seed layers 250 in the trenches 241.

In one embodiment, isolation structures may be further formed on the semiconductor substrate 201 to cover a portion of the sidewalls of the fins 202. The isolation structures have top surfaces lower than top surfaces of the fins 202. The isolation structures may be made of silicon dioxide, for example.

In one embodiment, the semiconductor device may further include spacers 230 on the sidewalls of the gate structures 210. Trenches 241 may be formed in the base substrate 200 on sides of the gate structures 210 and the spacers 230.

In one embodiment, the seed layers 250 and the source/drain layers 260 may be doped with conductive ions and the concentration of the conductive ions in the seed layers 250 may be less than the concentration of the conductive ions in the source/drain layers 260.

In other embodiments, the seed layers 250 may not have conductive ions.

When the semiconductor device is an N-type device, the seed layers 250 may be made of silicon or silicon carbide with conductive ions; the source/drain layers 260 may be made of silicon or silicon carbide with conductive ions, and the conductive ions may be N-type conductive ions.

When the semiconductor device is a P-type device, the seed layers 250 may be made of silicon germanium with conductive ions; the source/drain layers 260 may be made of silicon germanium with conductive ions; the concentration of germanium ions in the source/drain layers 260 may be greater than the concentration of germanium ions in the seed layers 250; and the conductive ions may be P-type conductive ions.

The concentration of the conductive ions in the seed layers 250 may be approximately 1% to 5% of the concentration of conductive ions in the source/drain layers 260.

The average thickness of the seed layer 250 at the bottom of the trench 241 may be larger than the average thickness of the seed layer 250 at the sidewall of the trench 241.

The average thickness of the seed layer 250 at the bottom of the trench 241 may be approximately 10 nm to 16 nm, and the average thickness of the seed layer 250 at the sidewall of the trench 241 may be approximately 6 nm to 8 nm.

In a certain embodiment, FinFET device may be formed by the spike annealing and silicon germanium seed process. For example, the Si recess corners may be rounded off and the Si recess sidewalls may be smoothed. The Si lattice damage may be repaired during the p-MOS silicon recess (PSR) etching. A continuous seed coverage inside the walls of the trenches 240 (referring to FIG. 5) and a seed profile with higher thickness at bottom and lower thickness at sidewalls may be achieved.

In the present disclosure, the inner walls of the initial trenches may be treated by a surface smoothing process. This surface smoothing process may provide smooth surfaces at the corners between the bottom and the sidewalls of the trenches, provide gradual transitions from the sidewall surfaces to the bottom surfaces of the trenches, and also provide less surface roughness at the corners between the bottom and the sidewalls of the trenches. This surface smoothing process may also repair the lattice damage at the corners between the bottom and the sidewalls of the initial trenches. Correspondingly, the surface smoothing process may reduce surface defects and lower the surface state density at the corners between the bottom and the sidewalls of the initial trenches. The seed layers may be formed at the corners between the bottom surfaces and sidewalls of the trenches. With a constant thickness of the seed layer, the seed layer may cover the inner walls of the trench. The seed layer may be served as a transition buffer layer for the growth of the source/drain layer, which may avoid the growth of the source/drain layer on a portion of the inner wall surface of the trench during the formation of the source/drain layer. The source/drain layers may only grow on the surfaces of the seed layers, which may reduce the lattice defects of the source/drain layers at the corners between the bottom and the side walls of the trenches and may improve the quality of the source/drain layers and the performance of the semiconductor devices.

In the present disclosure, the seed layer may be served as a transition buffer layer for the growth of the source/drain layer. The corner between the bottom surface and the sidewall of the trench may be rounded. With a constant thickness of the seed layer, the seed layer may cover inner walls of the trench, which may avoid the contact between the source/drain layer and a portion of the inner wall surface of the trench and may reduce the lattice defects of the source/drain layer at the corner between the bottom and the side wall of the trench. This may improve the quality of the source/drain layer and the performance of the semiconductor device.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A fabrication method of a semiconductor device, comprising:
providing a base substrate having a gate structure formed thereon;
forming initial trenches in the base substrate on sides of each gate structure;
smoothing inner wall surfaces of the initial trenches to form trenches from the initial trenches, wherein a corner between a bottom surface and a sidewall of each trench is rounded;
forming a seed layer on inner walls of each trench, wherein the seed layer covers all inner walls of each trench; and
forming source/drain layers on surfaces of the seed layers in the trenches.

2. The fabrication method according to claim 1, wherein:
smoothing the inner wall surfaces includes an annealing treatment.

3. The fabrication method according to claim 2, wherein:
the annealing treatment includes a spike annealing.

4. The fabrication method according to claim 2, wherein:
parameters in the annealing treatment include:
a gas including N₂, H₂ or a combination thereof;
an annealing temperature of approximately 800 degrees Celsius to 1000 degrees Celsius; and
an annealing pressure of approximately 5 torr to 50 torr.

5. The fabrication method according to claim 1, wherein:
the seed layers and the source/drain layers are doped with conductive ions, and a concentration of the conductive ions in the seed layers is less than a concentration of the conductive ions in source/drain layers.

6. The fabrication method according to claim 5, wherein:
when a semiconductor device is an N-type device,
the seed layers are made of silicon or silicon carbide with the conductive ions;
the source/drain layers are made of silicon or silicon carbide; and
the conductive ions are N-type conductive ions.

7. The fabrication method according to claim 5, wherein:
when a semiconductor device is a P-type device,
the seed layers are made of silicon germanium with the conductive ions;
the source/drain layers are made of silicon germanium with the conductive ions;
a concentration of germanium ions in the source/drain layers is greater than a concentration of germanium ions in the seed layers; and
the conductive ions are P-type conductive ions.

8. The fabrication method according to claim 5, wherein:
the concentration of the conductive ions in the seed layers is approximately 1% to 5% of the concentration of conductive ions in the source/drain layers.

9. The fabrication method according to claim 5, wherein:
the seed layers are made of silicon germanium with the conductive ions and the conductive ions are boron ions;
the seed layers are formed by an epitaxial growth process, including:
a gas including SiH₂Cl₂, GeH₄, B₂H₆, HCl or a combination thereof;
a flow rate of SiH₂Cl₂ of approximately 100 sccm to 200 sccm;
a flow rate of GeH₄ of approximately 8 sccm to 21 sccm;
a flow rate of B₂H₆ of approximately 15 sccm to 50 sccm;
a flow rate of HCl of approximately 50 sccm to 100 sccm;
a temperature of approximately 660 degrees Celsius to 680 degrees Celsius; and
a chamber pressure of approximately 100 torr to 200 torr.

10. The fabrication method according to claim 1, wherein:
the semiconductor device is an N-type device and the seed layers are made of silicon;
the seed layers are formed by an epitaxial growth process, including:
a gas including SiH₂Cl₂, HCl, or a combination thereof;
a flow rate of SiH₂Cl₂ of approximately 100 sccm to 200 sccm;
a flow rate of HCl of approximately 50 sccm to 100 sccm;
a temperature of approximately 700 degrees Celsius to 750 degrees Celsius; and
a chamber pressure of approximately 100 torr to 200 torr.

11. The fabrication method according to claim 1, wherein:
an average thickness of the seed layer on the bottom surface of the trench is larger than an average thickness of the seed layer on the sidewall of the trench.

12. The fabrication method according to claim 11, wherein:
the average thickness of the seed layer on the bottom surface of the trench is approximately 10 nm to 16 nm, and the average thickness of the seed layer at the sidewall of the trench is approximately 6 nm to 8 nm.

13. The fabrication method according to claim 1, wherein:
the source/drain layers are formed by an epitaxial growth process.

14. A semiconductor device, comprising:
a base substrate;
gate structures on the base substrate, wherein the base substrate contains trenches formed on sides of each gate structure, and a corner between a bottom surface and a sidewall of each trench is rounded;
a seed layer formed on inner walls of each trench, wherein the seed layer covers all of the inner walls of each trench; and
source/drain layers formed on the seed layers in the trenches.

15. The semiconductor device according to claim 14, wherein:
the seed layers and the source/drain layers are doped with conductive ions, and
a concentration of the conductive ions in the seed layers is less than a concentration of the conductive ions in the source/drain layer.

16. The semiconductor device according to claim 15, wherein:
when the semiconductor device is an N-type device,
the seed layers are made of silicon or silicon carbide with conductive ions;
the source/drain layers are made of silicon or silicon carbide with the conductive ions, and
the conductive ions are N-type conductive ions.

17. The semiconductor device according to claim 15, wherein:
when the semiconductor device is a P-type device,
the seed layers are made of silicon germanium with conductive ions;
the source/drain layers are made of silicon germanium with conductive ions and the concentration of germanium ions in the source/drain layers is greater than the concentration of germanium ions in the seed layers; and
the conductive ions are P-type conductive ions.

18. The semiconductor device according to claim 15, wherein:
the concentration of the conductive ions in the seed layers is 1% to 5% of the concentration of conductive ions in the source/drain layers.

19. The semiconductor device according to claim 14, wherein:
the average thickness of the seed layer at the bottom of the trench is larger than the average thickness of the seed layer at the sidewall of the trench.

20. The semiconductor device according to claim 19, wherein:
the average thickness of the seed layer at the bottom of the trench is 10 nm to 16 nm, and the average thickness of the seed layer at the sidewall of the trench is 6 nm to 8 nm.
